(19) United States
(12) Patent Application Publication
(10) Pub. No.: US 2023/0275168 A1
(43) Pub. Date: Aug. 31, 2023

(54) A packaging adhesive film and a photovoltaic module

(71) Applicant: HANGZHOU FIRST APPLIED MATERIAL CO.,LTD., Hangzhou, Zhejiang (CN)

(72) Inventors: Mingjie CAO, Hangzhou, Zhejiang (CN); Guangda ZHOU, Hangzhou, Zhejiang (CN)

(21) Appl. No.: 18/016,452

(22) PCT Filed: May 8, 2021
(86) PCT No.: PCT/CN2021/092477

§ 371 Date: Jan. 16, 2023

(30) Foreign Application Priority Data
Jul. 17, 2020 (CN) 202010699950.3

(51) Int. Cl. H01L 31/048; H01L 31/043

(52) U.S. Cl. CPC H01L 31/0481; H01L 31/043

(57) ABSTRACT

The disclosure provides a packaging adhesive film and a photovoltaic module. The packaging adhesive film includes a planar base layer and a buffer layer, the buffer layer is arranged on a surface of the planar base layer, and the buffer layer includes a plurality of buffer parts arranged at intervals, each one of the buffer part includes a long strip-shaped protrusion, and the long strip-shaped protrusion is arranged in a position corresponding to a photovoltaic ribbon, or arranged in a position corresponding to a cell piece gap in a photovoltaic module, or arranged in a position corresponding to a position of a depression of a lap portion of a laminated photovoltaic module, or arranged in a position corresponding to a position of a depression of a lap portion of a stacked tile photovoltaic module. The packaging adhesive film is simple in structure, and as the disclosure only aims at thickening the part of the packaging adhesive film corresponding to the position where a cell piece is prone to a micro-crack, a fracture and grating breakage, compared with the thickening of the whole packaging adhesive film in the prior art, the packaging adhesive film of the disclosure solves the probability of the reliability problems such as a micro-crack, a fracture and grating breakage occur to the cell piece in the packaging and laminating process of the photovoltaic module, as well as greatly reduces the production cost.

### CROSS-REFERENCE TO RELATED APPLICATIONS

The present application is a National Stage of International Patent Application No: PCT/CN2021/092477 filed on May 8, 2021, which application claims the benefit of priority to the Chinese patent application No. 202010699950.3 filed on Jul. 17, 2020, which is herein incorporated by reference in their entirety.

### TECHNICAL FIELD

The disclosure relates to the technical field of photovoltaic power generation, and in particular to a packaging adhesive film and a photovoltaic module.

### BACKGROUND

With the increasingly serious energy and environmental problems, it is urgent to use clean and renewable energy, herein, a photovoltaic power generation technology has developed rapidly and become increasingly mature, and the application of a photovoltaic cell has gradually become popular. In order to further improve the conversion efficiency of the photovoltaic cell, reduce the preparation cost, and realize cheap access to the Internet, new module technologies are constantly developing. With the development of new module technologies. Such as multi-grid, half-sheet, stacked sheet, stacked tile, patchwork and stacked welding, etc., the power of a module is greatly improved in comparison with that of an ordinary photovoltaic module. With the development of technology, the thickness of a cell piece is gradually decreasing. However, compared with an ordinary photovoltaic module, the photovoltaic module using the above cell technologies and module technologies obviously increase the risk of a cell piece fracture, a micro-crack, grating breakage, etc. in the service process, and even has a higher probability in the cell piece or module production process.

A packaging material plays the role of bonding protection on modules, and a conventional packaging material such as EVA film can increase the reliability of the modules to a certain extent. However, the reliability of a conventional packaged high-efficiency new cell and module cannot be ignored, and more stringent requirements are put forward for the packaging material. Usually, a high-weight packaging adhesive film can solve the above-mentioned related problems to a certain extent, but the high-weight packaging adhesive film costs more, which does not facilitate the cost reduction of modules.

### SUMMARY

The disclosure mainly aims to provide a packaging adhesive film and a photovoltaic module, so as to solve the problem of high production cost when the packaging adhesive film in a prior art solves the reliability problems such as a micro-crack, a fracture and grating breakage, etc. occur to a cell piece in the packaging and laminating process of the photovoltaic module.

In order to achieve the above purpose, the disclosure provides a packaging adhesive film, the packaging adhesive film comprises a planar base layer and a buffer layer, the buffer layer is arranged on a surface of the planar base layer, and the buffer layer comprises a plurality of buffer parts arranged at intervals, each one of the buffer part comprises a long strip-shaped protrusion, and the long strip-shaped protrusion being arranged in a position corresponding to a photovoltaic ribbon, or arranged in a position corresponding to a cell piece gap in the photovoltaic module, or arranged in a position corresponding to a position of a depression of a lap portion, of a laminated photovoltaic module, or arranged in a position corresponding to a position of a depression of a lap portion, of a stacked tile photovoltaic module.

Further, the width of the long strip-shaped protrusion is 0.3-30 mm, preferably 0.5-15 mm, and the thickness of the long strip-shaped protrusion is 10-600 μm, preferably 30-400 μm.

Further, each one of the long strip-shaped protrusion comprises spacing segments and protruding segments which are alternately arranged, the spacing segments being arranged corresponding to a photovoltaic ribbon in the position of recessed relative lap section of the laminated photovoltaic module, or arranged corresponding to the photovoltaic ribbon in the position of recessed relative lap section of the stacked tile photovoltaic module.

Further, the planar base layer and the buffer layer are integrally arranged.

Further, the planar base layer and the buffer layer are made of the same material.

Further, the planar base layer and the buffer layer are made of different materials, preferably, the planar base layer and the buffer layer being independently of each other selected from EVA or POE, preferably, a foaming structure being distributed in the buffer layer, and preferably the foam open cell ratio of the buffer layer being 10-80%.

Further, the planar base layer is a three-layer composite structure, the middle layer of the three-layer composite structure being a foaming material, the two outer layers of the three-layer composite structure being independently of each other selected from EVA or POE, the buffer layer is preferably selected from EVA or POE.

According to another aspect of the disclosure, a photovoltaic module is provided, the photovoltaic module comprising a packaging adhesive film, and the packaging adhesive film is any one of the aforementioned packaging adhesive films.

Further, the photovoltaic module being a multi-grid photovoltaic module, and the long strip-shaped protrusion of the packaging adhesive film is arranged corresponding to a photovoltaic ribbon of the multi-grid photovoltaic module.

Further, the photovoltaic module is selected from any one of a laminated photovoltaic module, a spliced photovoltaic module, a stacked tile photovoltaic module and a half-cell photovoltaic module, the long strip-shaped protrusion being arranged in a position corresponding to a cell piece gap, or arranged in a position corresponding to a position of a depression of a lap portion of the laminated photovoltaic module, or arranged in a position corresponding to a position of a depression of a lap portion of the stacked tile photovoltaic module.

As multiple-grid protrude from the surface of a cell piece, and there were overlapping areas among half-cell, laminated sheet, laminated tile, spliced and stitch-welded new photovoltaic modules, steps may be formed, accordingly, the joint is thick, and then stress concentration may exist in the laminating process of the photovoltaic modules, resulting in a thin packaging adhesive film at the joint during lamination, and further causing a micro-crack, a fracture or grating breakage of the cell piece. In view of this, according to the disclosure, through the improvement that the buffer layer is arranged on a surface of the planar base layer of the packaging adhesive film, the buffer layer includes a plurality of buffer parts arranged at intervals, each one of the buffer part includes a long strip-shaped protrusion, and the long strip-shaped protrusion is arranged in a position corresponding to a photovoltaic ribbon, or in a position corresponding to a cell piece gap in the photovoltaic module, or in a position corresponding to a position of a depression of a lap portion of a laminated photovoltaic module, or in a position corresponding to a position of a depression of a lap portion of a stacked tile photovoltaic module, the probability of the reliability problems such as the micro-crack, the fracture and the grating breakage occur to the cell piece in the packaging and laminating process of the photovoltaic module is reduced. The packaging adhesive film is simple in structure, and as the disclosure only aims at thickening the part of the packaging adhesive film corresponding to the position where the cell piece is prone to the micro-crack, the fracture and the grating breakage, therefore, compared with the thickening of the whole packaging adhesive film in the prior art, the packaging adhesive film of the disclosure solved the reliability problems such as the micro-crack, the fracture and the grating breakage occur to the cell piece in the packaging and laminating process of the photovoltaic module, as well as greatly reduces the production cost.

### BRIEF DESCRIPTION OF THE DRAWINGS

The drawings consisting of a part of the disclosure are used for further understanding of the present disclosure, the schematic embodiments and description thereof are used for explaining the disclosure and do not limit the disclosure improperly. In the drawings,

FIG. 1 illustrates a top view of a packaging adhesive film according to an embodiment of the disclosure.

FIG. 2 illustrates a schematic cross section of the packaging adhesive film of the FIG. 1 in AA′ direction.

FIG. 3 illustrates a top view of another packaging adhesive film according to an embodiment of the disclosure.

FIG. 4 illustrates a schematic cross section of the packaging adhesive film of the FIG. 3 in BB′ direction.

FIG. 5 illustrates a top view of yet another packaging adhesive film according to an embodiment of the disclosure, and

FIG. 6 illustrates a stacked tile photovoltaic module according to an embodiment of the disclosure.

Herein, the above drawings include the following reference numbers.

10 represents a planar base layer; 20 represents a buffer layer; 30 represents a buffer part; 001 represents a front transparent packaging layer; 002 represents a first packaging adhesive film layer; 003 represents a cell piece array; 004 represents a second packaging adhesive film layer; 005 represents a back packaging layer.

### DETAILED DESCRIPTION OF THE EMBODIMENTS

It is to be noted that the embodiments of the application and the features in the embodiments may be combined with each other without conflict, the disclosure will be described in detail with reference to the accompanying drawings and embodiments.

It should be noted that the following detailed description is illustrative and is intended to provide a further description of the present application. Unless otherwise indicated, all technical and scientific terms used herein have the same meaning as that commonly understood by those of ordinary skill in the art to which the present application belongs.

For convenient description, spatially relativity terms such as “on”, “above”, “on the surface of”, “on the top of” may be used herein to describe the spatial positional relationship of one device or one feature to other devices or features as shown in the drawings. It will be understood that the spatially relativity terms are intended to encompass different orientations used or operated in addition to the orientations of the devices described in the drawings. For example, if the device in the drawings is inverted, the device described as “on other devices or configurations” or “above other devices or configurations” will then be positioned “under other devices or configurations” or “below other devices or configurations.” Thus, the exemplary term “above” may include both orientations of “above” and “below”. The device may also be positioned in other different ways (rotated 90° or at other orientations) and the spatially relativity description used herein is interpreted accordingly.

As analyzed by a background art of the disclosure, the packaging adhesive film in the prior art has the problem of high production cost when solving the reliability problems such as a micro-crack, a fracture and grating breakage, etc. occur to a cell piece in a photovoltaic module, to solve the problem, the disclosure provides a packaging adhesive film and a photovoltaic module.

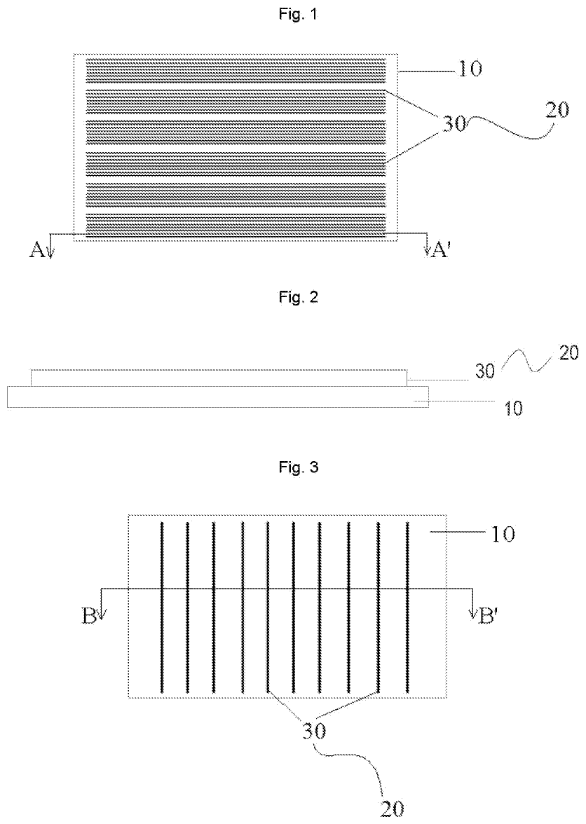

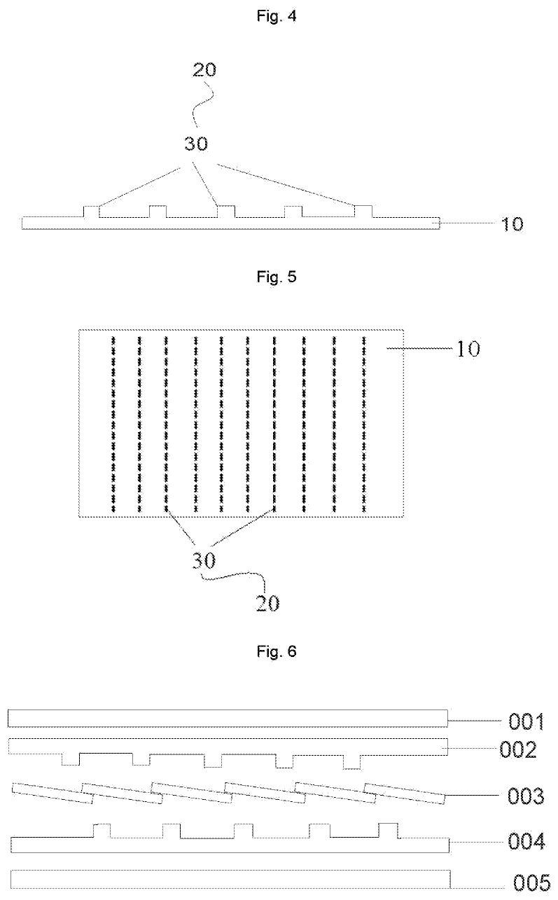

In a typical implementation mode of the disclosure, a packaging adhesive film is provided, as shown in the FIGS. 1-5, the packaging adhesive film comprises a planar base layer 10 and a buffer layer 20, the buffer layer 20 is arranged on a surface of the planar base layer 10, and the buffer layer 20 comprises a plurality of buffer parts 30 arranged at intervals, each one of the buffer part 30 comprises a long strip-shaped protrusion, and the long strip-shaped protrusion being arranged in a position corresponding to a photovoltaic ribbon, or arranged in a position corresponding to a cell piece gap in a photovoltaic module, or arranged in a position corresponding to a position of a depression of a lap portion of a laminated photovoltaic module, or arranged in a position corresponding to a position of a depression of a lap portion of a stacked tile photovoltaic module.

As multiple-grid protrude from the surface of a cell piece, and there are overlapping areas among half-cell, laminated sheet, laminated tile, spliced and stitch-welded new photovoltaic modules, steps may be formed, accordingly, the joint is thick, and then stress concentration may exist in the laminating process of the photovoltaic modules, resulting in a thin packaging adhesive film at the joint during lamination, and further causing a micro-crack, a fracture or grating breakage of the cell piece. In view of this, according to the disclosure, through the improvement that the buffer layer 20 is arranged on a surface of the planar base layer 10 of the packaging adhesive film, the buffer layer 20 includes a plurality of buffer parts 30 arranged at intervals, each one of the buffer part 30 includes a long strip-shaped protrusion, and the long strip-shaped protrusion is arranged in a position corresponding to a photovoltaic ribbon, or arranged in a position corresponding to a cell piece gap in the photovoltaic module, or arranged in a position corresponding to a position of a depression of a lap portion of a laminated photovoltaic module, or arranged in a position corresponding to a position of a depression of a lap portion of a stacked tile photovoltaic module, the probability of the reliability problems such as the micro-crack, the fracture and the grating breakage occur to the cell piece in the packaging and laminating process of the photovoltaic module is reduced. The packaging adhesive film is simple in structure, and as the disclosure only aims at thickening the part of the packaging adhesive film corresponding to the position where the cell piece is prone to the micro-crack, the fracture and the grating breakage, therefore, compared with the thickening of the whole packaging adhesive film in the prior art, the packaging adhesive film of the disclosure solves the reliability problems such as the micro-crack, the fracture and the grating breakage occur to the cell piece in the packaging and laminating process of the photovoltaic module, as well as greatly reduces the production cost.

In order to improve the matching between the long strip-shaped protrusion of the packaging adhesive film and the position of the photovoltaic ribbon, or the position of the cell piece gap in the photovoltaic module, or the position of a depression of a lap portion of the laminated photovoltaic module, or the position of a depression of a lap portion of the stacked tile photovoltaic module, on the basis of solving the reliability problems such as the micro-crack, the fracture and the grating breakage occur to the cell piece in the packaging and laminating process of the photovoltaic module as far as possible, without causing waste to the packaging adhesive film, preferably the width of the long strip-shaped protrusion is 0.3-30 mm, preferably 0.5-15 mm, and the thickness of the long strip-shaped protrusion is 10-600 μm, preferably 30-400 μm.

In an embodiment of the disclosure, as shown in the FIG. 5 or FIG. 6, each one of the long strip-shaped protrusions includes spacing segments and protruding segments which are alternately arranged, the spacing segments being arranged corresponding to a photovoltaic ribbon in the position of recessed relative lap section of the laminated photovoltaic module, or arranged corresponding to a photovoltaic ribbon in the position of recessed relative lap section of the stacked tile photovoltaic module.

The long strip-shaped protrusions of the packaging adhesive film are arranged into alternate spacing segments and protruding segments, so that on the basis that the long strip-shaped protrusions are arranged in a position corresponding to the cell piece gap in the photovoltaic module, or arranged in a position corresponding to a position of a depression of a lap portion of the laminated photovoltaic module, or arranged in a position corresponding to a position of a depression of a lap portion of the stacked tile photovoltaic module, the spacing segments are arranged corresponding to the photovoltaic ribbon in the position of a depression of a lap portion of the laminated photovoltaic module, or arranged corresponding to the photovoltaic ribbon in the position of a depression of a lap portion of the stacked tile photovoltaic module, and the probability of the reliability problems such as the micro-crack, the fracture and the grating breakage occur to the cell piece in the packaging and laminating process of the photovoltaic module may be further reduced.

In order to avoid the dislocation of the buffer layer 20 and the planar base layer 10, accordingly causing the structure of each one of the buffer part 30 to coincide with the overlapping area between the busbars or cell pieces in the laminating process of the photovoltaic module, as shown in FIG. 3, the planar base layer 10 and the buffer layer 20 are integrally arranged.

In one embodiment of the disclosure, the planar base layer 10 and the buffer layer 20 are made of the same material.

The above-mentioned planar base layer 10 and buffer layer 20 of the disclosure are made of the same material, and there is no special requirement for the material, same may be arranged with reference to the conventional packaging adhesive film material in the prior art, for example, material such as EVA or POE may be selected. The manufacturing method of the packaging adhesive film may refer to the manufacturing process of the packaging adhesive film in the prior art, for example, in the disclosure, an extrusion casting process may be adopted, and an embossing roll is set for a structure of the buffer part 30, after passing through the embossing roll and a rubber roll, the packaging adhesive film may form a long strip-shaped protrusion at a corresponding place, so as to obtain the packaging adhesive film in the disclosure.

In one embodiment of the disclosure, the planar base layer 10 and the buffer layer 20 are made of different materials, preferably, the planar base layer 10 and the buffer layer 20 being independently of each other selected from EVA or POE, preferably, a foaming structure being distributed in the buffer layer 20, and preferably the foam open cell ratio of the buffer layer 20 being 10-80%.

The planar base layer 10 and the buffer layer 20 are made of different materials, in order to improve the softness of the buffer layer 20 and increase its buffering effect on the stress in the laminating process of the photovoltaic module, the buffer layer with the above foam open cell ratio is preferred. The planar base layer 10 of the disclosure may be prepared by referring to an extrusion casting process in the prior art, and the buffer layer 20 may be obtained by screen printing, ink jet, coating and other processes.

In an embodiment of the disclosure, the planar base layer 10 is a three-layer composite structure, the middle layer of the three-layer composite structure being a foaming material, the two outer layers of the three-layer composite structure being independently of each other selected from EVA or POE, and the buffer layer 20 being preferably selected from EVA or POE.

The planar base layer 10 is arranged as a three-layer composite structure with the foaming material as the middle layer, which may also indirectly increase the buffering effect of the buffer layer 20 on the stress in the laminating process of the photovoltaic module. Accordingly, the reliability of the photovoltaic module in the packaging and laminating process is improved. The manufacturing method of the three-layer composite structure may refer to the three-layer co-extrusion process in the prior art, foaming agent is added to the middle layer, and in the extrusion casting process, the middle layer forms a film with a cellular structure, while the two side layers are common films in the prior art.

In another typical implementation mode of the disclosure, referring to the FIG. 6, a photovoltaic module is provided, the photovoltaic module may include a packaging adhesive film, and the packaging adhesive film is the aforementioned packaging adhesive film.

According to the disclosure, through the improvement that a buffer layer 20 is arranged on a surface of a planar base layer 10 of the packaging adhesive film, the buffer layer 20 includes a plurality of buffer parts 30 arranged at intervals, each one of the buffer part 30 includes a long strip-shaped protrusion, and the long strip-shaped protrusion is arranged in a position corresponding to a photovoltaic ribbon, or arranged in a position corresponding to a cell piece gap in the photovoltaic module, or arranged in a position corresponding to a position of a depression of a lap portion of a laminated photovoltaic module, or arranged in a position corresponding to a position of a depression of a lap portion of a stacked tile photovoltaic module. As multiple-grid protrude from the surface of a cell piece, and there are overlapping areas among half-cell, laminated sheet, laminated tile, spliced and stitch-welded new photovoltaic modules, steps may be formed, accordingly, the joint is thick, and then stress concentration may exist in the laminating process of the photovoltaic modules, resulting in a thin packaging adhesive film at the joint during lamination, and further causing the micro-crack, the fracture or the grating breakage of the cell piece. In view of this, if the packaging adhesive film is used as the packaging adhesive film of the multi-grid, the half-cell, the laminated sheet, the laminated tile, the spliced, and the stitch-welded new photovoltaic modules, the probability of the reliability problems such as the micro-crack, the fracture and the grating breakage occur to the cell piece in the packaging and laminating process of the photovoltaic module may be reduced. Moreover, as the disclosure only aims at thickening the part of the packaging adhesive film corresponding to the position where the cell piece is prone to the micro-crack, the fracture and the grating breakage, compared with the thickening of the whole packaging adhesive film in the prior art, the disclosure greatly reduces the production cost.

The manufacturing method of the photovoltaic module in the disclosure may refer to the conventional manufacturing method of the photovoltaic module in the prior art, such as laminating a front transparent packaging layer 001, a first packaging adhesive film layer 002, a cell piece array 003, a second packaging adhesive film layer 004 and a back packaging layer 005 which are sequentially stacked to obtain the photovoltaic module. The cell piece array 003 herein may be a multi-grid cell piece array, or a cell piece array formed by half-cell, lamination, shingling, splicing, stitch-welding and another connection manner, and the first packaging adhesive film layer 002 and the second packaging adhesive film layer 004 adopt the above-mentioned packaging adhesive film of the disclosure, so as to reduce the probability of reliability problems such as the micro-crack, the fracture and the grating breakage occur to the cell piece in the packaging and laminating process of the photovoltaic module.

In one embodiment of the disclosure, the photovoltaic module being a multi-grid photovoltaic module and the long strip-shaped protrusion of the packaging adhesive film is arranged corresponding to a photovoltaic ribbon of the multi-grid photovoltaic module.

The photovoltaic ribbon protruding from the surface of the cell piece in the multi-grid photovoltaic module may improve the conductive efficiency of the photovoltaic module, especially a circular photovoltaic ribbon, but same also brings about the grating breakage problem of the photovoltaic module in the laminating process, therefore, the packaging adhesive film with the long strip-shaped protrusion in the disclosure is employed and arranged corresponding to the photovoltaic ribbon of the multi-grid photovoltaic module, which may solve the grating breakage and other problems of the multi-grid photovoltaic module in the laminating process.

In one embodiment of the disclosure, the photovoltaic module is selected from any one of a laminated photovoltaic module, a spliced photovoltaic module, a stacked tile photovoltaic module and a half-cell photovoltaic module, the long strip-shaped protrusion is arranged in a position corresponding to the cell piece gap, or arranged in a position corresponding to a position of a depression of a lap portion of the laminated photovoltaic module, or arranged in a position corresponding to a position of a depression of a lap portion of the stacked tile photovoltaic module.

The packaging adhesive film of the disclosure is employed, and the long strip-shaped protrusion thereof is arranged in a position corresponding to the cell piece gap, or arranged in a position corresponding to a position of a depression of a lap portion of the laminated photovoltaic module, or arranged in a position corresponding to a position of a depression of a lap portion of the stacked tile photovoltaic module, so that the packaging adhesive film in the position of the cell piece gap, or in the position of a depression of a lap portion of the laminated photovoltaic module, or in the position of a depression of a lap portion of the stacked tile photovoltaic module is thick, thereby alleviating the problem that the packaging adhesive film at the joint is thin when laminating due to the stress existing in the laminating process of the photovoltaic module, and further solving the problems of the micro-crack and the fracture of the cell piece of the photovoltaic module.

The beneficial effects of the disclosure may be explained below in combination with specific embodiments and comparative examples.

### Embodiment 1

Referring to the FIG. 6, a front transparent packaging layer 001, a first packaging adhesive film layer 002, a cell piece array 003, a second packaging adhesive film layer 004 and a back packaging layer 005 were sequentially stacked and laminated to form a stacked tile photovoltaic module. Herein, the top views of the first packaging adhesive film layer 002 and the second packaging adhesive film layer 004 were shown in the FIG. 5, both the first packaging adhesive film layer 002 and the second packaging adhesive film layer 004 were EVA films including a planar base layer 10 and a buffer layer 20, the buffer layer 20 was provided with a cellular structure with the foam open cell ratio of 80%, and the planar base layer 10 and the buffer layer 20 were integrally arranged. The buffer layer 20 includes a plurality of buffer parts 30 arranged at intervals, each one of the buffer part included a long strip-shaped protrusion, and the long strip-shaped protrusion included spacing segments and protruding segments which were alternately arranged, the spacing segments were arranged corresponding to the photovoltaic ribbon in the position of recessed relative lap section of the stacked tile photovoltaic module, the long strip-shaped protrusion was arranged in a position corresponding to a position of a depression of a lap portion of the stacked tile photovoltaic module, the width of the long strip-shaped protrusion was 0.3 mm, and the thickness of the long strip-shaped protrusion was 10 μm, no cell piece breakage occurred during the abovementioned lamination process.

### Embodiment 2

The difference between Embodiment 2 and Embodiment 1 was that:

The buffer layer 20 was provided with a cellular structure with the foam open cell ratio of 20%, the width of the long strip-shaped protrusion was 0.5 mm, the thickness of the long strip-shaped protrusion was 30 μm, the long strip-shaped protrusion was arranged in a position corresponding to a position of a depression of a lap portion of the stacked tile photovoltaic module, and no cell piece breakage occurred during the abovementioned lamination process.

### Embodiment 3

The difference between Embodiment 3 and Embodiment 1 was that:

The buffer layer 20 was provided with a cellular structure with the foam open cell ratio of 50%, the width of the long strip-shaped protrusion was 5 mm, and the thickness of the long strip-shaped protrusion was 100 μm, the long strip-shaped protrusion was arranged in a position corresponding to a position of a depression of a lap portion of the stacked tile photovoltaic module, and no cell piece breakage occurred during the abovementioned lamination process.

### Embodiment 4

The difference between Embodiment 4 and Embodiment 1 was that:

The width of the long strip-shaped protrusion was 30 mm, the thickness of the long strip-shaped protrusion was 600 μm, the long strip-shaped protrusion was arranged in a position corresponding to a position of a depression of a lap portion of the stacked tile photovoltaic module, and no cell piece breakage occurred during the abovementioned lamination process.

### Embodiment 5

The difference between Embodiment 5 and Embodiment 1 was that:

The width of the long strip-shaped protrusion was 15 mm, the thickness of the long strip-shaped protrusion was 400 μm, the long strip-shaped protrusion was arranged in a position corresponding to a position of a depression of a lap portion of the stacked tile photovoltaic module, and no cell piece breakage occurred during the abovementioned lamination process.

### Embodiment 6

The difference between Embodiment 6 and Embodiment 1 was that:

The buffer layer 20 was provided with a cellular structure with the foam open cell ratio of 15%, the width of the long strip-shaped protrusion was 0.2 mm, the thickness of the long strip-shaped protrusion was 5 μm, the long strip-shaped protrusion was arranged in a position corresponding to a position of a depression of a lap portion of a stacked tile photovoltaic module, and no cell piece breakage occurred during the abovementioned lamination process.

### Embodiment 7

The difference between Embodiment 7 and Embodiment 1 was that:

The planar base layer 10 was a three-layer composite structure, the middle layer thereof was made of a foaming material, the two outer layers were made of EVA, and no cell piece breakage occurred during the lamination process.

### Embodiment 8

The difference between Embodiment 8 and Embodiment 1 was that:

The photovoltaic module was a multi-grid photovoltaic module, the cross-sectional views of the first packaging adhesive film layer 002 and the second packaging adhesive film layer 004 were both shown in the FIG. 1, and the top views thereof were both shown in the FIG. 3, each one of the buffer part included a long strip-shaped protrusion, and the long strip-shaped protrusion was arranged corresponding to the photovoltaic ribbon, no grating breakage occurred in the abovementioned lamination process.

### Comparative Example 1

The difference between comparative example 1 and Embodiment 1 was that:

The buffer part was arranged in a plane, and part of the cell pieces were broken during the lamination process.

It was to be seen from the above descriptions that the above-mentioned embodiments of the disclosure have achieved the following technical effects.

As multiple-grid protrude from the surface of a cell piece, and there were overlapping areas among half-cell, laminated sheet, laminated tile, spliced and stitch-welded new photovoltaic modules, steps may be formed, accordingly, the joint is thick, and then stress concentration may exist in the laminating process of the photovoltaic modules, resulting in a thin packaging adhesive film at the joint during lamination, and further causing a micro-crack, a fracture or grating breakage of the cell piece. In view of this, according to the disclosure, through the improvement that the buffer layer is arranged on a surface of the planar base layer of the packaging adhesive film, the buffer layer includes a plurality of buffer parts arranged at intervals, each one of the buffer part includes a long strip-shaped protrusion, and the long strip-shaped protrusion is arranged in a position corresponding to a photovoltaic ribbon, or in a position corresponding to a cell piece gap in the photovoltaic module, or in a position corresponding to a position of a depression of a lap portion of a laminated photovoltaic module, or in a position corresponding to a position of a depression of a lap portion of a stacked tile photovoltaic module, the probability of the reliability problems such as the micro-crack, the fracture and the grating breakage occur to the cell piece in the packaging and laminating process of the photovoltaic module is reduced. The packaging adhesive film is simple in structure, and as the disclosure only aims at thickening the part of the packaging adhesive film corresponding to the position where the cell piece is prone to the micro-crack, the fracture and the grating breakage, therefore, compared with the thickening of the whole packaging adhesive film in the prior art, the packaging adhesive film of the disclosure solved the reliability problems such as the micro-crack, the fracture and the grating breakage occur to the cell piece in the packaging and laminating process of the photovoltaic module, as well as greatly reduced the production cost.

The above is only the preferred embodiments of the disclosure and is not used to limit the disclosure. For those skilled in the art, there may be various changes and variations in the disclosure. Any modifications, equivalent replacements, improvements and the like made within the spirit and principle of the disclosure shall fall within the scope of protection of the disclosure.

1. A packaging adhesive film, the packaging adhesive film comprises a planar base layer and a buffer layer, wherein the buffer layer is arranged on a surface of the planar base layer, the buffer layer comprises a plurality of buffer parts arranged at intervals, each one of the buffer part comprises a long strip-shaped protrusion, and the long strip-shaped protrusion being arranged in a position corresponding to a photovoltaic ribbon, or arranged in a position corresponding to a cell piece gap in a photovoltaic module, or arranged in a position corresponding to a position of a depression of a lap portion of a laminated photovoltaic module, or arranged in a position corresponding to a position of a depression of a lap portion of a stacked tile photovoltaic module.

2. The packaging adhesive film according to claim 1, wherein the width of the long strip-shaped protrusion is 0.3-30 mm, preferably 0.5-15 mm, the thickness of the long strip-shaped protrusion is 10-600 μm, preferably 30-400 μm.

3. The packaging adhesive film according to claim 1, wherein each one of the long-strip-shaped protrusion comprises spacing segments and protruding segments which are alternately arranged, the spacing segments being arranged corresponding to a photovoltaic ribbon in the position of recessed relative lap section of the laminated photovoltaic module, or arranged corresponding to a photovoltaic ribbon in the position of recessed relative lap section of the stacked tile photovoltaic module.

4. The packaging adhesive film according to claim 1, wherein the planar base layer and the buffer layer are integrally arranged.

5. The packaging adhesive film according to claim 1, wherein the planar base layer and the buffer layer are made of the same material.

6. The packaging adhesive film according to claim 1, wherein the planar base layer and the buffer layer are made of different materials, preferably, the planar base layer and the buffer layer being independently of each other selected from EVA or POE, preferably, a foaming structure being distributed in the buffer layer, and preferably the foam open cell ratio of the buffer layer being 10-80%.

7. The packaging adhesive film according to claim 1, wherein the planar base layer is a three-layer composite structure, the middle layer of the three-layer composite structure being a foaming material, the two outer layers of the three-layer composite structure being independently of each other selected from EVA or POE, the buffer layer being preferably selected from EVA or POE.

8. A photovoltaic module, the photovoltaic module comprising a packaging adhesive film, wherein the packaging adhesive film is the packaging adhesive film according to claim 1.

9. The photovoltaic module according to claim 8, the photovoltaic module being a multi-grid photovoltaic module, wherein the long strip-shaped protrusion of the packaging adhesive film is arranged corresponding to a photovoltaic ribbon of the multi-grid photovoltaic module.

10. The photovoltaic module according to claim 8, wherein the photovoltaic module is selected from any one of a laminated photovoltaic module, a spliced photovoltaic module, a stacked tile photovoltaic module and a half-cell photovoltaic module, the long strip-shaped protrusion being arranged in a position corresponding to a cell piece gap, or arranged in a position corresponding to a position of a depression of a lap portion of the laminated photovoltaic module, or arranged in a position corresponding to a position of a depression of a lap portion of the stacked tile photovoltaic module.
